(19) United States
(12) Patent Application Publication
(10) Pub. No.: US 2021/0140899 A1
(43) Pub. Date: May 13, 2021

(54) SUBSTRATE INSPECTION DEVICE

(71) Applicant: Samsung Electronics Co., Ltd., Suwon-si (KR)

(72) Inventors: Jangik PARK, Suwon-si (KR); Sungyoon RYU, Suwon-si (KR); Younghoon SOHN, Seoul (KR); Yusin YANG, Seoul (KR)

(73) Assignee: Samsung Electronics Co., Ltd., Suwon-si (KR)

(21) Appl. No.: 16/887,284

(22) Filed: May 29, 2020

(30) Foreign Application Priority Data
Nov. 8, 2019 (KR) 10-2019-0143000

(51) Int. Cl. G01N 21/956; G01N 21/95; G01N 21/21

(52) U.S. Cl. CPC G01N 21/95607; G01N 2021/213; G01N 21/211; G01N 21/9501

(57) ABSTRACT

A substrate inspection device including a light source, a polarizer, first and second compensators, an analyzer, a light splitter configured to receive reflected light reflected by the substrate to split the reflected light into first split light and second split light, a first detector and a second detector configured to detect the first split light and the second split light, respectively, and a controller configured to control the first and second detectors differently from each other, may be provided.

### CROSS-REFERENCE TO RELATED APPLICATION

This application claims priority under 35 U.S.C. ¶119 to Korean Patent Application No. 10-2019-0143000, filed on Nov. 8, 2019, in the Korean Intellectual Property Office, the disclosure of which is incorporated herein in its entirety by reference.

### BACKGROUND

The inventive concepts relate to substrate inspection devices. More specifically, the inventive concepts relate to substrate inspection devices for performing spectral ellipsometry inspection.

As a process of manufacturing a semiconductor device is highly integrated, technology for measuring a three-dimensional (3D) profile of a semiconductor fine pattern or complicated structures is being developed. Recently, in memories and logic products, fine process technology having a line width of 20 nm or less is being used, and accordingly, the significance of technology for monitoring a process of forming a fine pattern is increasing for enhancing a manufacturing yield rate and quality. A process monitoring speed is a significant factor for determining productivity in manufacturing a semiconductor device. Therefore, in non-destructive inspection for performing total inspection on substrates, the significance of an optical method having a high inspection speed is increasing.

### SUMMARY

The inventive concepts provide substrate inspection devices with enhanced accuracy and precision.

According to an example embodiment, a substrate inspection device includes a light source configured to irradiate non-polarized incident light onto a substrate, a polarizer between the light source and the substrate and configured to linearly polarize the incident light, a first compensator between the polarizer and the substrate, a light splitter configured to receive reflected light generated by the incident light reflected by the substrate, and split the reflected light into first split light and second split light, a second compensator between the substrate and the light splitter, an analyzer between the second compensator and the light splitter, a first detector and a second detector configured to detect the first split light and the second split light, respectively, a controller configured to control the first and second detectors, and a processor configured to process signals detected by the first and second detectors. The controller may be configured to rotate at least one of the polarizer, the first and second compensators, or the analyzer, and the controller may be configured to differently control the first and second detectors.

According to an example embodiment, a substrate inspection device includes a light source configured to irradiate non-polarized incident light onto a substrate, a polarizer between the light source and the substrate, a light splitter configured to receive reflected light generated by the incident light reflected by the substrate, and split the reflected light into first split light and second split light, an analyzer between the substrate and the light splitter, a first detector configured to operate in a chopping mode to detect the first split light, and a second detector configured to operate in a continuous mode to detect the second split light.

According to an example embodiment, a substrate inspection device includes a light source configured to irradiate incident light onto a substrate, a polarizer between the light source and the substrate to linearly polarize the incident light, a light splitter configured to split reflected light generated by the incident light reflected by the substrate, to generate a plurality of split lights, an analyzer between the light splitter and the substrate, and a plurality of detectors configured to detect the pieces of split light, respectively.

### BRIEF DESCRIPTION OF THE DRAWINGS

Example embodiments of the inventive concepts will be more clearly understood from the following detailed description taken in conjunction with the accompanying drawings in which:

FIG. 1 is a schematic diagram for describing spectral ellipsometry;

FIG. 2A is a conceptual view for describing a substrate inspection device according to an example embodiment;

FIG. 2B is a plan view illustrating a portion on a substrate that is inspected by the substrate inspection device;

FIGS. 3A and 3B are graphs for describing a measurement method of each of first and second detectors according to an example embodiment, in sequence;

FIGS. 4A and 4B are graphs for describing a measurement method of each of first and second detectors according to an example embodiments, in sequence;

FIG. 5 is a flowchart for describing a method of manufacturing a substrate, according to an example embodiment;

FIGS. 6A and 6B are graphs comparing measurement results between substrate inspection devices according to conventional art and substrate inspection devices according to conventional art and substrate inspection devices according to some embodiments; and

FIGS. 7A to 10B are diagrams for describing a substrate inspection device according to some different example embodiments.

### DETAILED DESCRIPTION

Hereinafter, some example embodiments will be described in detail with reference to the accompanying drawings. Like numeral references refer to like elements, and their repetitive descriptions are omitted.

FIG. 1 is a schematic diagram for describing spectral ellipsometry.

The spectral ellipsometry may be optical technology for inspecting a structural characteristic (e.g., a thickness of a thin film and/or a line width of a pattern formed in the thin film), and a dielectric characteristic (e.g., a complex refractive index and/or a dielectric function). The composition, roughness, thickness, depth, crystalline characteristic, doping concentration, and electrical conductivity of each of thin films included in an inspection target sample may be characterized by the spectral ellipsometry.

The spectral ellipsometry may be optical technology that compares a model with a variation in polarization before/after an interaction with a thin film such as reflection and transmission to determine a characteristic of the thin film. Here, the polarization variation may be represented by a reflection amplitude ratio Ψ and a phase difference Δ. The amplitude ratio may denote an amplitude variation ratio of a p wave and an s wave when light is reflected by a thin film. The phase difference may denote a phase variation difference between the p wave and the s wave when light is reflected by the thin film. Because the polarization variation depends on the kind and thickness of a material of the thin film, the thickness and optical constant of each of all kinds of films may be measured by a contactless manner. Based on the spectral ellipsometry, a single atomic layer, a single layer, or a multilayer having a thickness of several A to several μm may be characterized at high precision.

As illustrated in FIG. 1, non-polarized electromagnetic radiation emitted by a light source may be linearly polarized by a polarizer. Optionally, a first compensator such as a quarter wave plate and a retarder may be further disposed on a light path between the polarizer and a sample.

Radiation reflected by the sample may pass through a second polarizer referred to as an analyzer and may reach a detector. Finally, a second compensator may be disposed on a light path between an analyzer and the sample.

The spectral ellipsometry may be a specular reflection optical inspection method based on an incident angle and a reflection angle, and an incident beam and a reflected beam may be over an incident plane. Polarization in a direction parallel to the incident plane may be referred to as p-polarization, and polarization in a direction vertical to the p-polarization may be referred to as s-polarization.

The spectral ellipsometry may measure a complex reflectance ρ, which may be parameterized by the reflection amplitude ratio Ψ and the phase difference Δ. A polarization state of light incident on the sample may be decomposed into an s component and a p component. Hereinafter, amplitudes of after-reflection s and p components regularized to initial values may be referred to as rs and rp. In this case, rs, rp, and the complex reflectance p may satisfy the following Equation 1.

$$ρ = \frac{r p}{r s} = tan Ψ \cdot {e}^{i Δ} \qquad [ Equation 1 ]$$

An incident angle of light may be set to be close to a Brewster angle, and thus a difference between rs and rp may be maximized. The spectral ellipsometry may measure a ratio (or a difference) of two values, and thus may provide a measurement result, which is relatively precise and highly reproducible. Therefore, the spectral ellipsometry may not relatively be sensitive to variations in light scattering and a light inspection condition, and may not need a separate standard sample and reference light ray.

Except for simple cases like an infinite thickness film or a homogeneous film, the measured reflection amplitude ratio Ψ and phase difference Δ may not directly be converted into optical constants of the sample. Therefore, model analysis may be performed for obtaining an optical constant from a result of the spectral ellipsometry generally. As an example of the model, there may be a Forouhi bloomer model. The model may be based on physical energy transition, or may be based on free parameters for data fitting. The model may include a stacking order of layers included in the sample and an optical constant (for example, a refractive index or a dielectric function tensor) and a thickness parameter of each of individual layers.

The spectral ellipsometry may calculate the reflection amplitude ratio Ψ and the phase difference Δ by using iteration (e.g., a least square method) for varying an optical constant and/or a thickness parameter. The Fresnel equation may be used to calculate the reflection amplitude ratio Ψ and the phase difference Δ. When values of the calculated reflection amplitude ratio Ψ and phase difference Δ match experiment data, the optical constant and thickness values of thin films corresponding thereto may be determined as the optical constant and thickness values of thin films included in the sample.

FIG. 2A is a conceptual view for describing a substrate inspection device 100 according to an example embodiment. FIG. 2B is a plan view of a portion por on a substrate S that is inspected by the substrate inspection device 100.

Referring to FIGS. 2A and 2B, the substrate inspection device 100 may include a light source 110, a polarizer 120, first and second compensators 131 and 132, an analyzer 140, a light splitter 150, first and second detectors 161 and 162, a controller 170, a processor 180, and a tray 190. The substrate inspection device 100 may inspect the substrate S on which a series of processes of manufacturing a semiconductor device have been performed. The substrate inspection device 100 may be a spectral ellipsometer for performing the above-described spectral ellipsometry.

The substrate S may be disposed on the tray 190. The tray 190 may support and fix the substrate S while a semiconductor process and inspection are being performed. The tray 190 may move the substrate S to a desired position on the basis of performing inspection and a process. A direction vertical to a top surface of the substrate S disposed on the tray 190 may be referred to as a Z direction, and two directions parallel to the top surface of the substrate S and perpendicular to each other may be referred to as an X direction and a Y direction. For example, the tray 190 may move the substrate S in the X direction and the Y direction so that different portions por of the substrate S are inspected. The tray 190 may move the substrate S in the Z direction so that an optical system included in the substrate inspection device 100 is focused on the substrate S.

The substrate S may include, for example, silicon (Si). The substrate S may include a semiconductor element, such as germanium (Ge), or a compound semiconductor such as silicon carbide (SiC), gallium arsenide (GaAs), indium arsenide (InAs), or indium phosphide (InP). According to some example embodiments, the substrate S may have a silicon on insulator (SOI) structure. The substrate S may include a buried oxide layer. According to some example embodiments, the substrate S may include a conductive region (for example, an impurity-doped well). According to some example embodiments, the substrate S may have various isolation structures such as shallow trench isolation (STI) for separating the impurity-doped well.

The substrate S may be a wafer on which a process of manufacturing a semiconductor device has been performed. A process of manufacturing a semiconductor device may include, for example, i) an oxidation process of forming oxide, ii) a lithography process including a spin coating process, an exposure process, and a development process, iii) a thin film deposition process, iv) a dry or wet etching process, or v) a metal wiring process.

The oxidation process may be a process of forming thin and uniform silicon oxide by performing a chemical reaction between oxygen or vapor and a silicon substrate surface at a high temperature of about 800 degrees C. to about 1,200 degrees C. The oxidation process may include a dry oxidation process and a wet oxidation process. The dry oxidation process may form oxide by reacting oxygen and gas, and the wet oxidation process may form oxide by reacting oxygen and vapor.

According to some example embodiments, the SOI structure may be formed on the substrate S by the oxidation process. The substrate S may include the buried oxide layer. According to some example embodiments, the substrate S may have various isolation structures such as STI.

The lithography process may be a process of transferring a circuit pattern, previously formed on a lithography mask, to the substrate S through exposure. The lithography process may be performed, for example, in the order of the spin coating process, the exposure process, and the development process.

The thin film deposition process may be, for example, one of an atomic layer deposition (ALD) process, a chemical vapor deposition (CVD) process, a plasma-enhanced CVD (PECVD) process, a metal organic CVD (MOCVD) process, a physical vapor deposition (PVD) process, a reactive pulsed laser deposition process, a molecular beam epitaxy process, or a DC magnetron sputtering process.

The dry etching process may be, for example, one of a reactive ion etching (ME) process, a deep ME (DRIE) process, an ion beam etching (IBE) process, or an Ar milling process. As another example, the dry etching process performed on the substrate S may be an atomic layer etching (ALE) process. Further, the wet etching process performed on the substrate S may be an etching process using, as an etchant gas, at least one of Cl₂, HCl, CHF₃, CH₂F₂, CH₃F, H₂, BCL₃, SiCl₄, Bra, HBr, NF₃, CF₄, C₂F₆, C₄F₈, SF₆, O₂, SO₂, and COS.

The metal wiring process may be a process of forming a conductive wiring (e.g., a metal line), for implementing a circuit pattern for an operation of a semiconductor device. Transfer paths for transferring a ground voltage, power, and a signal for operating semiconductor devices may be formed by the metal wiring process. The metal wiring may include gold, platinum, silver, aluminum, and/or tungsten.

According to some example embodiments, an ion injection process and a planarization process such as a chemical mechanical polish (CMP) process may be further performed in a process of manufacturing a semiconductor device.

The substrate inspection device 100 may inspect a pattern and a layer each formed on the substrate S by at least one of the above-described processes. The substrate inspection device 100 may determine one of a thickness of a formed layer, a threshold dimension of a pattern formed at the layer, a height of the pattern, a recess, an overlay, and a defect. Here, the overlay may be an amount representing a degree of misalignment between a buffer layer and a photoresist pattern each formed previously.

The light source 110 may generate incident light IL, and may irradiate the generated incident light IL onto the substrate S. The incident light IL generated by the light source 110 may be non-polarized light. However, the present example embodiment is not limited thereto, and the incident light IL may be polarized light. The incident light IL may be incident in an inclined direction with respect to the top surface of the substrate S.

A wavelength of the incident light IL may be in a wavelength band of a desired (or alternatively, predetermined) range. According to some example embodiments, the incident light IL may be visible light. According to some example embodiments, a wavelength of the incident light IL may be about 400 nm to about 800 nm. According to some other example embodiments, the incident light IL may be near-infrared light or infrared light. According to some example embodiments, a wavelength band of the incident light IL may be about 800 nm to about 3,000 nm. The light source 110 may emit light of a certain wavelength, or may simultaneously emit light of various wavelengths. The light source 110 may emit light of a different wavelength over time.

The polarizer 120 may be disposed on a path of the incident light IL between the light source 110 and the substrate S. The polarizer 120 may determine a polarization direction of the incident light IL. The incident light IL passing through the polarizer 120 may include only the same component as the polarization direction of the incident light IL. Therefore, the incident light IL passing through the polarizer 120 may be linearly polarized. The first compensator 131 may be disposed on the path of the incident light IL between the polarizer 120 and the substrate S.

Reflected light RL reflected by the substrate S may reach the light splitter 150. The second compensator 132 and the analyzer 140 may be disposed on a light path between the light splitter 150 and the substrate S.

Depending on cases, one of the first and second compensators 131 and 132 may be omitted. The first compensator 131 may control a phase difference Δ of the incident light IL. The second compensator 132 may control a phase difference Δ of the reflected light RL.

The analyzer 140 may control a polarization direction of the reflected light RL reflected by the substrate S. Depending on cases, an imaging lens may be further disposed on a light path of the reflected light RL (e.g., between the analyzer 140 and the light splitter 150). The imaging lens may control the chromatic aberration of the reflected light RL.

Although not clearly shown in the drawing, at least one of the polarizer 120, the first and second compensators 131 and 132, and the analyzer 140 may be connected to a rotation driver (not shown) for controlling a polarization direction. For example, i) only one of the polarizer 120, the first and second compensators 131 and 132, or the analyzer 140 may be connected to the rotation driver, ii) each of the polarizer 120 and the analyzer 140 may be connected to the rotation driver, iii) each of the polarizer 120 and the first and second compensators 131 and 132 may be connected to the rotation driver, iv) each of the first and second compensators 131 and 132 and the analyzer 140 may be connected to the rotation driver, or v) each of the polarizer 120, the first and second compensators 131 and 132, and the analyzer 140 may be connected to the rotation driver.

The rotation driver (e.g., a step motor) connected to at least one of the polarizer 120, the first and second compensators 131 and 132, and the analyzer 140 may be connected to the controller 170. The rotation driver may be controlled by the controller 170. Therefore, a rotation of at least one of the polarizer 120, the first and second compensators 131 and 132, and the analyzer 140 may be controlled to a speed set by the controller 170.

At least one of the polarizer 120, the first and second compensators 131 and 132, and the analyzer 140 may rotate at a certain speed, or may rotate at a varying speed. For convenience of description, the inventive concepts will be described based on an example where at least one of the polarizer 120, the first and second compensators 131 and 132, and the analyzer 140 rotates at a certain angular speed. However, those of ordinary skill in the art may easily apply details described herein to a case where at least one of the polarizer 120, the first and second compensators 131 and 132, and the analyzer 140 rotates at a varying angular speed.

Light passing through the analyzer 140 may reach the light splitter 150. The light splitter 150 may be a prism, which is formed by processing a light-transmitting material (e.g., quartz). The light splitter 150 may split a single path of the reflected light RL into a plurality of paths. The light splitter 150 may generate first split light and second split light SL1 and SL2. In FIG. 2A, it is illustrated that the first split light SL1, which is transmission light, is detected by the first detector 161 and the second split light SL2, which is reflected light, is detected by the second detector 162, but a case opposite thereto may be implemented.

The first split light SL1 and the second split light SL2 generated by the light splitter 150 may respectively reach the first and second detectors 161 and 162. The first and second detectors 161 and 162 each may be one of a charge-coupled device (CCD) camera or a complementary metal oxide semiconductor (CMOS) image sensor. According to some example embodiments, the first and second detectors 161 and 162 each may be, for example, a spectral imaging camera, but are not limited thereto. The first and second detectors 161 and 162 may detect spectral images of the portions por of the substrate S. The first detector 161 may be configured to generate a first spectral image at a first wavelength band, and the second detector 162 may be configured to generate a second spectral image at a second wavelength band that is different from the first wavelength band. Signals (e.g., the first and second spectral images) generated by the first and second detectors 161 and 162 may be transferred to the processor 180. A ratio of a magnitude of the first split light SL1 to a magnitude of the second split light SL2 may be 5:5, but is not limited thereto. A ratio of a magnitude of the first split light SL1 to a magnitude of the second split light SL2 may be 6:4, 7:3, or 8:2.

Therefore, the first and second detectors 161 and 162 may detect the first split light SL1 and the second split light SL2 split from the reflected light RL reflected by the same portion por of the substrate S. According to some example embodiments, the portion por may have an oval shape in a top view. The portion por may have a long-axis length of about 35 μm and a short-axis length of about 25 μm, but is not limited thereto.

The first and second detectors 161 and 162 may generate electrical signals (e.g., spectral images) on the basis of detection results of the first split light SL1 and the second split light SL2. The first and second detectors 161 and 162 may generate the electrical signals (e.g., the spectral images) by using different methods. The first detector 161 may be a chopping mode detector. The second detector 162 may be a continuous mode detector. The first detector 161 may generate an electrical signal (e.g., a spectral image) corresponding to a certain time period (e.g., a relatively short time period) or a certain rotation angle. The first detector 161 may generate a period average of an electrical signal (e.g., a spectral image) corresponding to a certain continuous time period or a certain continuous rotation angle range.

The first and second detectors 161 and 162 may sample the reflected light RL at different times. In other words, the first and second detectors 161 and 162 may receive the first split light SL1 and the second split light SL2 split from the reflected light RL reflected by the same portion por of the substrate S, and may generate signals on the basis of reached pieces of light at different times.

The first and second detectors 161 and 162 may be connected to a certain driving device. Therefore, the first and second detectors 161 and 162 may respectively move along light paths of the first split light SL1 and the second split light SL2.

Hereinafter, measurement methods of the first and second detectors 161 and 162 will be described with reference to FIGS. 3A to 4B.

FIGS. 3A and 3B are graphs for describing a measurement method of each of the first and second detectors 161 and 162 according to an example embodiment, in sequence.

In FIGS. 3A and 3B, the abscissa axis represents time, and the ordinate axis represents a rotation angle of at least one of the polarizer 120, the first and second compensators 131 and 132, or the analyzer 140. The first and second compensators 131 and 132 and the analyzer 140 may rotate at a constant speed, and thus a time variation with respect to a rotation angle may be constant. Based on a symmetrical structure of the polarizer 120, a 180-degree rotation may be the same as or substantially similar to a 0-degree rotation and the first and second compensators 131 and 132 and the analyzer 140 may rotate at a constant speed, and thus a rotation angle may vary at a period T.

Referring to FIGS. 2A and 3B, the measurement of the first detector 161 may correspond to an arbitrary time or an arbitrary rotation angle. According to some example embodiments, the first detector 161 may measure the first split light SL1 at a time period after a first time t1 elapses for each period T of a rotation. According to some example embodiments, the first detector 161 may measure the first split light SL1 when an angle, by which the polarizer 120, the first and second compensators 131 and 132, and the analyzer 140 rotate, is a first angle θ1.

Measurement of the second detector 162 may correspond to an arbitrary time period or an arbitrary rotation angle range. The second detector 162 may measure the second split light SL2 from a second time t2 to a third time t3, with respect to the start of each period T of a rotation. According to some example embodiments, the second detector 162 may measure the second split light SL2 when an angle, by which the polarizer 120, the first and second compensators 131 and 132, and the analyzer 140 rotate, is a second angle θ2 to a third angle θ3.

A second real measurement time of the second detector 162 may be longer than a first real measurement time of the first detector 161. According to a configuration of the optical system illustrated in FIG. 2A, a time for which the first detector 161 inspects one portion por may be the same as a time for which the second detector 162 inspects the one portion por. Here, the first real measurement time may denote a time associated with generating of real data by the first detector 161, and the second real measurement time may denote a time associated with generating of real data by the second detector 162. For example, the first real measurement time may be a time for which the first detector 161 actually receives the first split light SL1 to generate a spectral image, and the second real measurement time may be a time for which the second detector 162 actually receives the second split light SL2 to generate a spectral image. In some example embodiments, the first real measurement time may denote a time period for which the processor 180 performs data analysis in a signal measured by the first detector 161, and the second real measurement time may denote a time period for which the processor 180 performs data analysis in a signal measured by the second detector 162.

In the example embodiment illustrated in FIGS. 3A and 3B, the second real measurement time may be t3−t2. According to some example embodiments, the second real measurement time may be about ten times the first real measurement time, but is not limited thereto. According to some example embodiments, the first real measurement time may be within a range of about 0.1 ms to about 1 ms, and the second real measurement time may be within a range of about 1 ms to about 10 ms. However, the inventive concepts are not limited thereto.

According to some example embodiments, a time for which the first detector 161 performs measurement may be included in a time period where the second detector 162 performs measurement. According to some example embodiments, an angle at which the first detector 161 performs measurement may be within an angle range where the second detector 162 performs measurement. For example, the first to third times t1 to t3 and the first to third angles θ1 to θ3 may satisfy the following Equation 2.

t2<t1<t3

θ2<θ1<θ3 [Equation 2]

However, the inventive concepts are not limited thereto, and a time for which the first detector 161 performs measurement may be outside a time period where the second detector 162 performs measurement. According to some example embodiments, an angle at which the first detector 161 performs measurement may be outside an angle range where the second detector 162 performs measurement. For example, the first to third times t1 to t3 and the first to third angles θ1 to θ3 may satisfy the following Equation 3.

0[s]<t3<t1 or t2<t3<T

0°<θ3<θ1 or θ2<θ3<180° [Equation 3]

FIGS. 4A and 4B are graphs for describing a measurement method of each of the first and second detectors 161 and 162 according to an example embodiment, in sequence.

The illustrations of the graphs of FIGS. 4A and 4B are similar to the illustrations of FIGS. 4A and 4B, and thus, for convenience of description, a repetitive description thereof is omitted and a difference therebetween will be mainly described.

Referring to FIGS. 2A, 4A, and 4B, unlike FIG. 3A, the first detector 161 may measure the first split light SL1 during a desired (or alternatively, predetermined) time period or a desired (or alternatively, predetermined) angle range. The first detector 161 may measure the first split light SL1 from a fourth time t4 to a fifth time t5 with respect to a start point of each period T. The first detector 161 may measure the first split light SL1 when an angle, by which the polarizer 120, the first and second compensators 131 and 132, and the analyzer 140 rotate, is in a range between a fourth angle θ4 and a fifth angle θ5.

According to some example embodiments, a first real measurement time t5−t4 of the first detector 161 may be shorter than a real measurement time t3−t2 of the second detector 162. According to some other example embodiments, the first real measurement time t5−t4 of the first detector 161 may be the same as or substantially similar to the real measurement time t3−t2 of the second detector 162.

According to some example embodiments, a measurement time period [t4, t5] of the first detector 161 may partially overlap a real measurement time [t2, t3] of the second detector 162. According to some example embodiments, the measurement time period [t4, t5] of the first detector 161 may not overlap the real measurement time [t2, t3] of the second detector 162. According to some example embodiments, the measurement time period [t4, t5] of the first detector 161 may be the same as or substantially similar to the real measurement time [t2, t3] of the second detector 162. According to some other example embodiments, the measurement time period [t4, t5] of the first detector 161 may be included in the real measurement time [t2, t3] of the second detector 162, or the real measurement time [t2, t3] of the second detector 162 may be included in the measurement time period [t4, t5] of the first detector 161.

According to some example embodiments, a measurement rotation angle range [θ4, θ5] of the first detector 161 may partially overlap a measurement rotation angle range [θ2, θ3] of the second detector 162. According to some example embodiments, the measurement rotation angle range [θ4, θ5] of the first detector 161 may not overlap the measurement rotation angle range [θ2, θ3] of the second detector 162. According to some example embodiments, the measurement rotation angle range [θ4, θ5] of the first detector 161 may be the same as or substantially similar to the measurement rotation angle range [θ2, θ3] of the second detector 162. According to some other example embodiments, the measurement rotation angle range [θ4, θ5] of the first detector 161 may be included in the measurement rotation angle range [θ2, θ3] of the second detector 162, or the measurement rotation angle range [θ2, θ3] of the second detector 162 may be included in the measurement rotation angle range [θ4, θ5] of the first detector 161.

Referring again to FIGS. 2A and 2B, the controller 170 may control the overall inspection of the substrate S by the substrate inspection device 100. The controller 170 may control the horizontal-direction relative movement of the tray 190 with respect to the optical system so as to inspect different portions por of the substrate S.

As described above, the controller 170 may control a rotation of at least one of the polarizer 120, the first and second compensators 131 and 132, and the analyzer 140.

The controller 170 may control the movements of the first and second detectors 161 and 162 through light paths of the first split light SL1 and the second split light SL2, respectively. Therefore, resolutions of the first and second detectors 161 and 162 may be controlled. According to some example embodiments, the resolution of the first detector 161 may be the same as or substantially similar to that of the second detector 162. According to some example embodiments, the resolution of the first detector 161 may differ from that of the second detector 162. According to some example embodiments, the resolution of the first detector 161 may be greater than that of the second detector 162. According to some example embodiments, the resolution of the first detector 161 may be less than that of the second detector 162.

The controller 170 may control measurement by the first and second detectors 161 and 162 on the basis of an operation result of the processor 180. The controller 170 may control first and second real measurement times of the first and second detectors 161 and 162. The controller 170 may control an operation of the processor 180.

The controller 170 may control a rotation of at least one of the polarizer 120, the first and second compensators 131 and 132, and the analyzer 140, and may synchronize the rotation of the at least one element with detection times for detecting the first split light SL1 and the second split light SL2 by the first and second detectors 161 and 162. Therefore, the controller 170 may control the first and second detectors 161 and 162 to accurately perform detection at a desired rotation angle.

The processor 180 may differently process spectral images generated by the first and second detectors 161 and 162. For example, in the example embodiment illustrated in FIGS. 3A and 3B, the processor 180 may obtain an average of a spectral image of the first detector 161 corresponding to a first angle θ1 and may obtain an average of a spectral image of the second detector 162 corresponding to a rotation angle range from a second angle θ2 to a third angle θ3.

As another example, in the example embodiment illustrated in FIGS. 4A and 4B, the processor 180 may obtain an average of a spectral image of the first detector 161 corresponding to a rotation angle range from a fourth angle θ4 to a fifth angle θ5, and may obtain an average of a spectral image of the second detector 162 corresponding to the rotation angle range from the second angle θ2 to the third angle θ3.

The processor 180 may calculate a reflection amplitude ratio Ψ and a phase difference Δ each corresponding to a signal measured from each of the first and second detectors 161 and 162 while varying an optical constant and/or a thickness parameter by using the iteration method (e.g., the least square method).

The processor 180 may determine a rotation angle, a wavelength band, and a resolution each corresponding to an optimal condition of a measurement parameter on the basis of analyzing signals generated by the first and second detectors 161 and 162. Here, as described above, the rotation angle may denote a rotation angle of at least one of the polarizer 120, the first and second compensators 131 and 132, or the analyzer 140.

According to some example embodiments, the processor 180 may include at least one of a data analyzer and an optical critical dimension (OCD) measuring instrument including a spectrum recognition algorithm. Here, the OCD measuring instrument may be a device for extracting physical parameters of the portions por of the substrate S from spectrum data. The spectrum recognition algorithm of the OCD measuring instrument may use a rigorous coupled-wave analysis (RCWA) algorithm. The RCWA algorithm may be used to describe diffraction or reflection of an electromagnetic wave from a surface of a grating structure. However, the inventive concepts are not limited thereto, and the processor 180 may use one of a spectral image, spectral ellipsometry analysis algorithm and a multi-point high speed measurement spectral ellipsometry analysis algorithm, for monitoring a profile change trend in the substrate S. Further, the processor 180 may use a parameter separation algorithm such as a correlation analysis algorithm, a main component analysis algorithm, or a rank test for extracting a profile change value from a plurality of spectrums.

According to some example embodiments, the processor 180 may determine a first angle θ1 or a first time t1 of the first detector 161 responding to a measurement parameter which is to be measured by the substrate inspection device 100. According to some example embodiments, the processor 180 may determine a measurement angle range or a first time period of the second detector 162 responding to the measurement parameter which is to be measured by the substrate inspection device 100.

According to some example embodiments, the processor 180 may detect a wavelength band responding to the measurement parameter which is to be measured by the substrate inspection device 100, with respect to each of the first and second detectors 161 and 162. According to some other example embodiments, the processor 180 may select a wavelength band, where match ability between an inspection result of the substrate inspection device 100 and a real structure of the substrate S is high as known through destructive inspection, as a measurement range of each of the first and second detectors 161 and 162. Therefore, a wavelength band where the first detector 161 generates a spectral image may be the same as or different from a wavelength band where the second detector 162 generates a spectral image.

In this manner, the substrate inspection device 100 may determine optimal conditions of a wavelength band and a resolution for each parameter and detector. The substrate inspection device 100 may obtain and use a rotation angle set, wavelength bands, and resolutions satisfying an optimal condition, for monitoring a measurement parameter, thereby checking the variation or not of a measurement parameter based on a process.

Here, the controller 170 and the processor 180 may each be implemented as hardware, firmware, or an arbitrary combination of hardware and software.

For example, the controller 170 and the processor 180 each may be a computing device such as a workstation computer, a desktop computer, a laptop computer, or a tablet computer. The controller 170 and the processor 180 each may be simple controller, a microprocessor, a central processing unit (CPU), a complicated processor such as a graphics processing unit (GPU), a processor configured by a combination of hardware and software, dedicated hardware, or firmware. The controller 170 and the processor 180 each may be, for example, a general-use computer, a digital signal processor (DSP), or application specific hardware such as field programmable gate array (FPGA) or application specific integrated circuit (ASIC).

According to some example embodiments, operations of the controller 170 and the processor 180 may be implemented as instructions which are stored in a machine-readable medium and are readable and executable by one or more processors. Here, the machine-readable medium may include an arbitrary mechanism for storing and/or transmitting information in the form readable by a machine (e.g., a computing device). For example, the machine-readable medium may include read only memory (ROM), random access memory (RAM), a magnetic disk storage medium, an optical storage medium, and flash memory devices and may store an electrical, optical, acoustic, or another type of radio signal (e.g., a carrier, an infrared signal, or a digital signal) and other arbitrary signals.

Firmware, software, routine, and instructions may be configured for performing the operations of the controller 170 and the processor 180 described above or an arbitrary process described below. For example, the operations of the controller 170 may be implemented by software which generates a signal for inspecting the substrate S and receives data for feedback corresponding to an optimal inspection condition from the processor 180. The operations of the processor 180 may be implemented by software which performs an arithmetic operation on an inspection result to determine an optical condition (e.g., the kind and thickness of a material of a thin film) of a sample.

However, this is for convenience of description, and it may be understood that the operations of the controller 170 and the processor 180 described above are based on a computing device, a processor, a controller, or another device for executing firmware, software, routine, and instructions.

FIG. 5 is a flowchart of a method of manufacturing a substrate, according to an example embodiment.

The method of manufacturing a substrate, according to some example embodiments, may include operation P10 of optimizing an optical inspection parameter, operation P20 of inspecting a substrate S, operation P30 of determining a physical characteristic of the substrate S, and operation P40 of performing a semiconductor device manufacturing process.

Operation P10 of optimizing the optical inspection parameter may include i) determining a first angle which is a measurement angle by the first detector 161 and a second angle range, which is a measurement angle range by the second detector 162, ii) determining a measurement wavelength band of the first detector 161 and a measurement wavelength band of the second detector 162, and iii) determining a resolution of the first detector 161 and a resolution of the second detector 162.

Based on an optimization result determined in operation P10, the substrate S may be inspected in operation P20. Operation P20 of inspecting the substrate S may be the same as or substantially similar to the description given above with reference to FIGS. 1 to 4.

Operation P30 of determining the physical characteristic of the substrate S may include the OCD inspection and the thickness inspection each described above.

In operation P40, the semiconductor device manufacturing process may be performed based on a result of the inspection.

For example, when the physical characteristic determined in operation P30 is an overlay of the substrate S, the overlay may be compared with an allowable value in operation P40. When the allowable value is greater than the overlay, a lithography process may be performed again after a photoresist pattern is removed, and when the allowable value is equal to or less than the overlay, a subsequent process such as an etching process may be performed.

As another example, in a case where a feedback signal is generated based on the thickness, film uniformity, or critical dimension of a layer deposited on the substrate S obtained in operation P30, a subsequent process may be controlled in operation P40. The control of the subsequent process may be performed based on a feedback manner such as wafer-to-wafer, lot-to-lot, or wafer-to-lot. Therefore, reliability in manufacturing a semiconductor device may be enhanced.

FIGS. 6A and 6B are graphs comparing measurement results between substrate inspection devices according to conventional art and substrate inspection devices according to some example embodiments.

In FIGS. 6A and 6B, a comparative example shows results of measurements by a substrate inspection device including a single detector of the conventional art, and an experiment example shows results of measurements by a substrate inspection device including a plurality of detectors for measuring split reflected pieces of light. Further, para1 to para4 of FIGS. 6A and 6B represent results of different semiconductor inspection devices.

FIG. 6A shows a standard deviation of a thickness measured based on the comparative example and the experiment example. Referring to FIG. 6A, compared to the comparative example, it may be seen that the experiment example has a smaller standard deviation of measurement thicknesses, and thus the measurement precision is enhanced.

FIG. 6B shows a standard correlation coefficient between a true value and a thickness measured based on the comparative example and the experiment example. Referring to FIG. 6B, compared to the comparative example, it may be seen that the experiment example has a higher correlation coefficient than the comparative example, and thus the measurement accuracy is enhanced.

FIGS. 7A and 7B are diagrams for describing substrate inspection devices 200a and 200b according to some different example embodiments.

For convenience of description, description which is the same as or similar to description given above with reference to FIG. 2A is omitted, and a difference will be mainly described.

Except for that the substrate inspection device 200a of FIG. 7A includes a light splitter 250a configured by an optical fiber, the substrate inspection device 200a may be the same as or substantially similar to the substrate inspection device 100 illustrated in FIG. 2A. According to some example embodiments, the light splitter 250a may include a fused biconic taper (FBT) having a type where two optical fibers are bonded by heat applied thereto and are stretched, and thus are thinned.

The substrate inspection device 200b of FIG. 7B, unlike FIG. 7A, may include a light splitter 250b configured by coupling three optical fibers. Therefore, the light splitter 250b may split a light path of reflected light RL into three light paths, and first to third detectors 161 to 163 may be respectively provided in the three light paths. Each of the first to third detectors 161 to 163 may have a configuration similar to that of one of the first and second detectors 161 and 162 of FIG. 2A.

In an example embodiment, the first detector 161 may operate in the chopping mode, and the second and third detectors 162 and 163 may operate in the continuous mode. In this case, the second and third detectors 162 and 163 may generate spectral images in different rotation angle ranges, respectively.

In another example embodiment, the first and third detectors 161 and 163 may operate in the chopping mode, and the second detector 162 may operate in the continuous mode. In this case, the first and third detectors 161 and 163 may generate spectral images at different rotation angles, respectively.

According to some other example embodiments, a light splitter for splitting a light path of the reflected light RL into a plurality of light paths may be provided by coupling four or more optical fibers, and different detectors may be respectively connected to the light paths.

FIGS. 8A to 8C are diagrams for describing a substrate inspection device 300 according to an example embodiment.

For convenience of description, description which is the same as or similar to description given above with reference to FIG. 2A is omitted, and a difference will be mainly described.

According to some example embodiments, unlike the substrate inspection device 100 of FIG. 2A, the substrate inspection device 300 of FIGS. 8A to 8C may include a light splitter 350 of a planar lightwave circuit (PLC) type, which is manufactured on a silica substrate by using lithography technology.

The light splitter 350 may include an oxide layer 352 and a silicon layer 353. A grating coupler implemented to have a concave-convex pattern may be formed in the silicon layer 353. Reflected light RL incident on an approximate center portion of the grating coupler 353G may be split, and may travel along the silicon layer 353. The reflected light RL may be incident to be substantially vertical to the grating coupler 353G, but is not limited thereto.

As illustrated in FIG. 8B, the reflected light RL may be introduced into the grating coupler 353G through an optical fiber 351, for the light efficiency of the light splitter 350. However, the inventive concepts are not limited thereto, and depending on the case, the optical fiber 351 may be omitted.

The reflected light RL may be introduced into the silicon layer 353 by controlling a concave-convex interval and depth of the grating coupler 353G. A refractive index of the silicon layer 353 may be greater than that of the oxide layer 352, and thus first split light SL1 and the second split light SL2 may be entirely reflected, and may travel along first and second light waveguides 355 and 357, respectively. That is, the silicon layer 353 may be a core layer, and the oxide layer 352 may be a cladding layer. According to some example embodiments, a cladding layer (e.g., an oxide layer) may be provided on the silicon layer 353, and an upper portion of the silicon layer 353 may be covered by the cladding layer.

As illustrated in FIG. 8C, the first and second light waveguides 355 and 357 may be provided at both sides of the grating coupler 353G, respectively, and the first split light SL1 and the second split light SL2 may travel in opposite directions. The light splitter 350 may include first and second tapers 354 and 356, which are disposed between the grating coupler 353G and the first and second light waveguides 355 and 357 to connect the grating coupler 353G to the first and second light waveguides 355 and 357. Therefore, the first split light SL1 and the second split light SL2 may be input to the first and second light waveguides 355 and 357 through the first and second tapers 354 and 356, respectively. First and second detectors 161 and 162 may be disposed at end portions of the first and second light waveguides 355 and 357 to detect the first split light SL1 and the second split light SL2, respectively.

FIGS. 9A and 9B are diagrams for describing a substrate inspection device 400 according to an example embodiment.

For convenience of description, description which is the same as or similar to description given above with reference to FIGS. 8A to 8C is omitted, and a difference will be mainly described.

A light splitter 450 illustrated in FIGS. 9A and 9B may be a PLC type, the same as or substantially similar to FIG. 8B. According to some example embodiments, the light splitter 450 may include a grating coupler 453G, a taper 454, and a Y-shaped split pipe 455.

The light splitter 450 of FIGS. 9A and 9B may include a light waveguide, which is provided in only one direction of the grating coupler 453G. In the present example embodiment, reflected light RL may be obliquely incident on the light splitter 450, but is not limited thereto.

According to some example embodiments, the reflected light RL incident on the Y-shaped split pipe 455 through the taper 454 may be split, and may be incident on first and second detectors 161 and 162. According to some other example embodiments, the Y-shaped split pipe 455 may be replaced by a one-to-many optical interferometry. Therefore, a light path of the reflected light RL may be split into a plurality of light paths, and detectors may be respectively disposed on the light paths.

FIGS. 10A and 10B are diagrams for describing substrate inspection devices 500a and 500b according to some example embodiments.

In the example embodiments of FIGS. 10A and 10B, the substrate inspection device 500a may include a diffraction grating 550a, and the substrate inspection device 500b may include a diffraction grating 550b.

The diffraction grating 500a of FIG. 10A may be a transmissive type.

According to some example embodiments, 1^{st}-order diffraction light may reach the first detector 161, and 1^{st}-order diffraction light may reach the second detector 162. According to some other example embodiments, 0^{th}-order diffraction light may reach the first detector 161, and the 1^{st}-order diffraction light may reach the second detector 162. In this case, the diffraction grating 550a may be a phase grating which allows a magnitude of the 0^{th}-order diffraction light to be equal to or substantially similar to that of the 1^{st}-order diffraction light. However, the present example embodiment is not limited thereto, and the first and second detectors 161 and 162 may be respectively disposed on light paths of two arbitrary diffraction lights.

Except for that the diffraction grating 500b of FIG. 10B is a reflective diffraction grating, the diffraction grating 500b of FIG. 10B may be the same as or substantially similar to the diffraction grating 500a of FIG. 10A.

While the inventive concepts have been particularly shown and described with reference to some example embodiments thereof, it will be understood that various changes in form and details may be made therein without departing from the spirit and scope of the following claims.

What is claimed is:

1. A substrate inspection device comprising:
a light source configured to irradiate non-polarized incident light onto a substrate;
a polarizer between the light source and the substrate and configured to linearly polarize the incident light;
a first compensator between the polarizer and the substrate;
a light splitter configured to receive reflected light generated by the incident light reflected by the substrate, and split the reflected light into first split light and second split light;
a second compensator between the substrate and the light splitter;
an analyzer between the second compensator and the light splitter;
a first detector and a second detector configured to detect the first split light and the second split light, respectively;
a controller configured to control the first and second detectors; and
a processor configured to process signals detected by the first and second detectors,
wherein the controller is configured to rotate at least one of the polarizer, the first and second compensators, or the analyzer, and
the controller is configured to differently control the first and second detectors.

2. The substrate inspection device of claim 1, wherein
each of the first and second detectors comprises a spectral imaging camera,
the first detector is configured to generate a first spectral image at a first wavelength band, and
the second detector is configured to generate a second spectral image at a second wavelength band that is different from the first wavelength band.

3. The substrate inspection device of claim 1, wherein the controller is configured to move the first detector on a light path of the first split light.

4. The substrate inspection device of claim 1, wherein a first resolution of the first detector differs from a second resolution of the second detector.

5. The substrate inspection device of claim 1, wherein
the first detector is configured to detect the first split light when a rotation angle of at least one of the polarizer, the first and second compensators, or the analyzer is a first angle, and
the second detector is configured to detect the second split light when the rotation angle of at least one of the polarizer, the first and second compensators, or the analyzer is within a range from a second angle to a third angle.

6. The substrate inspection device of claim 5, wherein the first angle is within the range from the second angle to the third angle.

7. The substrate inspection device of claim 5, wherein the first angle is outside the range from the second angle to the third angle.

8. The substrate inspection device of claim 5, wherein the controller is configured to determine the first to third angles based on a processing result of the processor.

9. A substrate inspection device comprising:
a light source configured to irradiate non-polarized incident light onto a substrate;
a polarizer between the light source and the substrate;
a light splitter configured to receive reflected light generated by the incident light reflected by the substrate, and split the reflected light into first split light and second split light;
an analyzer between the substrate and the light splitter;
a first detector configured to operate in a chopping mode to detect the first split light; and
a second detector configured to operate in a continuous mode to detect the second split light.

10. The substrate inspection device of claim 9, wherein the light splitter is configured to further split the reflected light into third split light.

11. The substrate inspection device of claim 10, further comprising:
a third detector configured to operate in the chopping mode to detect the third split light.

12. The substrate inspection device of claim 10, further comprising:
a third detector configured to operate in the continuous mode to detect the third split light.

13. The substrate inspection device of claim 9, wherein the first and second detectors are configured to inspect the same portion of the substrate at different times.

14. The substrate inspection device of claim 9, further comprising:
a processor configured to calculate a first average of a first spectral image by the first detector and a second average of a second spectral image by the second detector.

15. A substrate inspection device comprising:
a light source configured to irradiate incident light onto a substrate;
a polarizer between the light source and the substrate to linearly polarize the incident light;
a light splitter configured to split reflected light generated by the incident light reflected by the substrate, to generate pieces of split light;
an analyzer between the light splitter and the substrate; and
a plurality of detectors configured to detect the pieces of split light, respectively.

16. The substrate inspection device of claim 15, wherein the light splitter comprises a prism.

17. The substrate inspection device of claim 15, wherein the light splitter comprises an optical fiber.

18. The substrate inspection device of claim 15, wherein the light splitter comprises a planar lightwave circuit (PLC).

19. The substrate inspection device of claim 15, wherein the light splitter comprises a diffraction grating.

20. The substrate inspection device of claim 15, wherein a number of the pieces of the split light is three or more.
